(19) United States
(12) Patent Application Publication
(10) Pub. No.: US 2026/0040633 A1
(43) Pub. Date: Feb. 5, 2026

(54) SEMICONDUCTOR DEVICES

(71) Applicant: SAMSUNG ELECTRONICS CO., LTD, SUWON-SI (KR)

(72) Inventor: Jongryeol Yoo, Suwon-si (KR)

(21) Appl. No.: 19/171,451

(22) Filed: Apr. 7, 2025

(30) Foreign Application Priority Data
Aug. 1, 2024 (KR) 10-2024-0102359

(51) Int. Cl. H10D 62/10; H01L 21/768; H10D 30/00; H10D 30/01

(52) U.S. Cl. CPC H10D 62/102; H10D 30/501; H10D 62/124; H01L 21/76831; H01L 21/76897; H10D 30/019

(57) ABSTRACT

A semiconductor device includes: an active pattern extending in a first direction and including a semiconductor material; a gate structure disposed on the active pattern, and extending in a second direction crossing the first direction; a plurality of channels spaced apart from each other in a third direction substantially perpendicular to the first and second directions; an etch stop pattern disposed on a lower surface of the gate structure; first and second source/drain layers disposed at opposite sides, respectively, of the gate structure, wherein each of the first and second source/drain layers contact the plurality of channels; a first contact plug disposed on an upper portion of the first source/drain layer; and a division structure extending through the active pattern and the etch stop pattern, wherein the division pattern is disposed on a lower surface of the gate structure.

### CROSS-REFERENCE TO RELATED APPLICATION

This application claims priority under 35 U.S.C. § 119 to Korean Patent Application No. 10-2024-0102359 filed on Aug. 1, 2024 in the Korean Intellectual Property Office, the disclosure of which is incorporated by reference herein in its entirety.

### TECHNICAL FIELD

Example embodiments of the present inventive concept relate to a semiconductor device.

### DISCUSSION OF RELATED ART

A semiconductor device may include a power rail for supplying power to each element. Generally, the power rail may be formed on an upper surface of a substrate together with a gate structure, a source/drain layer, a contact plug and upper wirings. However, as the integration degree of the semiconductor device increases, it may be difficult to form the power rail on the upper surface of the substrate with the contact plug and the upper wirings, and therefore, methods of forming the power rail on a bottom surface of the substrate are under development.

### SUMMARY

According to example embodiments of the present inventive concept, a semiconductor device includes: an active pattern extending in a first direction and including a semiconductor material; a gate structure disposed on the active pattern, and extending in a second direction crossing the first direction; a plurality of channels spaced apart from each other in a third direction substantially perpendicular to the first and second directions, wherein each of the plurality of channels are disposed in the gate structure; an etch stop pattern disposed on a lower surface of the gate structure; first and second source/drain layers disposed at opposite sides, respectively, of the gate structure, wherein each of the first and second source/drain layers contact the plurality of channels; a first contact plug disposed on an upper portion of the first source/drain layer; and a division structure extending through the active pattern and the etch stop pattern, wherein the division pattern is disposed on a lower surface of the gate structure.

According to example embodiments of the present inventive concept, a semiconductor device includes: a gate structure; a plurality of channels extending in a first direction and disposed in the gate structure, wherein the plurality of channels are spaced apart from each other in a second direction that is substantially perpendicular to the first direction; first and second source/drain layers disposed at opposite sides, respectively, of the gate structure, wherein each of the first and second source/drain layers contact the plurality of channels; a division structure between the first and second source/drain layers, wherein the division structure includes: a first division pattern having an upper surface contacting a lower surface of the gate structure; and a second division pattern extending through and contacting a lower portion of the first division pattern, wherein the second division pattern has an upper surface that is narrower than a lower surface of the first division pattern.

According to example embodiments of the present inventive concept, a semiconductor device includes: an active pattern extending in a first direction; an isolation structure covering a sidewall of the active pattern in a second direction crossing the first direction; a gate structure disposed on the active pattern, and extending in the second direction; a plurality of channels spaced apart from each other in a third direction that is substantially perpendicular to the first and second directions, wherein each of the plurality of channels are covered by the gate structure; an etch stop pattern contacting a lower surface of the gate structure; first and second source/drain layers disposed at each of opposite sides, respectively, of the gate structure, wherein each of the first and second source/drain layers contact the plurality of channels; a first contact plug disposed on and contacting an upper portion of the first source/drain layer; a second contact plug disposed on and contacting a lower portion of the second source/drain layer; a division structure disposed between the first source/drain layer and the second source/drain layer, wherein the division structure includes: a first division pattern having an upper surface contacting the lower surface of the gate structure; and a second division pattern extending through the active pattern and a lower portion of the first division pattern and contacting the first division pattern, wherein the second division pattern has an upper surface that is narrower than a lower surface of the first division pattern; and first and second wirings electrically connected to the first and second contact plugs, respectively.

### BRIEF DESCRIPTION OF THE DRAWINGS

FIGS. 1, 2 and 3 are a plan view and cross-sectional views illustrating a semiconductor device in accordance with example embodiments of the present inventive concept.

FIGS. 4, 5, 6, 7, 8, 9, 10, 11, 12, 13, 14, 15, 16, 17, 18, 19, 20, 21, 22, and 23 are plan views and cross-sectional views illustrating a method of manufacturing a semiconductor device in accordance with example embodiments of the present inventive concept.

FIG. 24 is a cross-sectional view illustrating a semiconductor device in accordance with example embodiments of the present inventive concept.

FIG. 25 is a cross-sectional view illustrating a method of manufacturing a semiconductor device in accordance with example embodiments of the present inventive concept.

### DETAILED DESCRIPTION OF THE EMBODIMENTS

The above and other aspects and features of a semiconductor device and a method of manufacturing the same in accordance with example embodiments of the present inventive concept will become readily understood from detail descriptions that follow, with reference to the accompanying drawings. It will be understood that, although the terms “first,” “second,” and/or “third” may be used herein to describe various materials, layers (films), regions, electrodes, pads, patterns, structures and processes, these materials, layers (films), regions, electrodes, pads, patterns, structures and processes should not be limited by these terms. These terms are only used to distinguish one material, layer (film), region, electrode, pad, pattern, structure and process from another material, layer (film), region, electrode, pad, pattern, structure and process. Thus, a first material, layer (film), region, electrode, pad, pattern, structure and process discussed below could be termed a second or third material, layer (film), region, electrode, pad, pattern, structure and process without departing from the scope and teachings of present inventive concept.

Hereinafter, in the specification (and not necessarily in the claims), two directions that are substantially perpendicular to each other among horizontal directions, which are substantially parallel to an upper surface of a substrate, may be referred to as first and second directions D1 and D2, respectively, and a vertical direction substantially perpendicular to the upper surface of the substrate may be referred to as a third direction D3. In example embodiments of the present inventive concept, the third direction D3 may be substantially perpendicular to the first and second directions D1 and D2. In example embodiments of the present inventive concept, the first and second directions D1 and D2 may be orthogonal to each other. Each of the first to third directions D1, D2 and D3 may represent not only a direction shown in the drawing, but also a reverse direction to the direction.

Example embodiments of the present inventive concept relate to a semiconductor device with enhanced electrical characteristics and increased integration. More specifically, example embodiments of the present inventive concept relate to overcoming challenges related to forming power rails and other structural elements in increasingly miniaturized and high-density semiconductor designs. This may be achieved by incorporating structural features, such as a division structure between source/drain layers and an etch stop pattern on a gate structure, to increase performance and mitigate issues like leakage currents.

The division structure may include a first division pattern and a second division pattern. These components are designed to isolate and prevent electrical leakage between source/drain layers while maintaining effective channel operation. The division structure may extend through an active pattern and etch stop layer, creating an electrical barrier that aligns with the gate structure to optimize transistor behavior.

Additionally, example embodiments of the present inventive concept may include a multi-bridge channel field-effect transistor (MBCFET) configuration, where multiple channels may be vertically spaced apart from each other. These channels may be disposed in a gate structure. The gate structure may include, for example, an etch stop pattern and capping layers, to ensure stability during fabrication and operation.

In example embodiments of the present inventive concept, the semiconductor device may include contact plugs and interlayer connections that enable reliable power delivery and signal integrity across the structure. In addition, according to example embodiments of the present inventive concept, a method for manufacturing high-performance semiconductor devices that can increase integration and power efficiency may be provided.

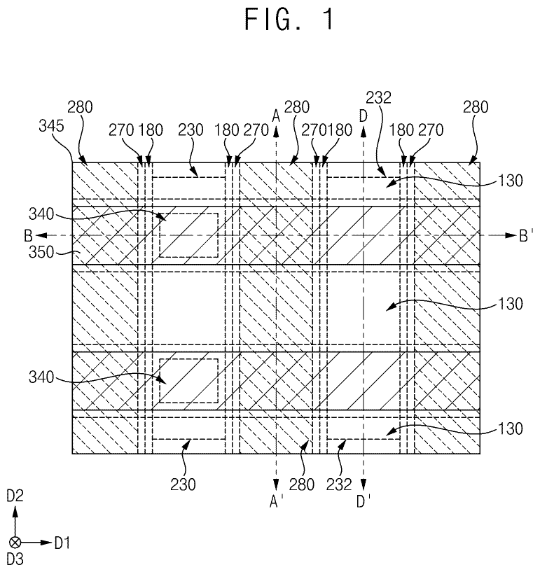

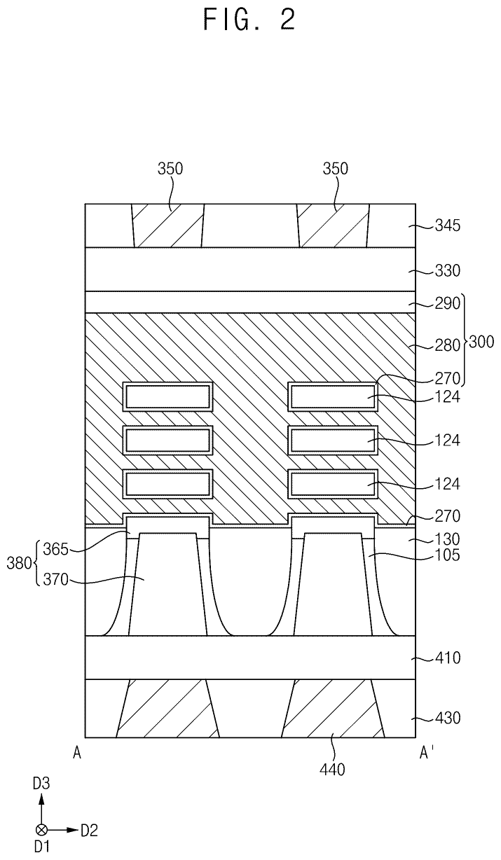

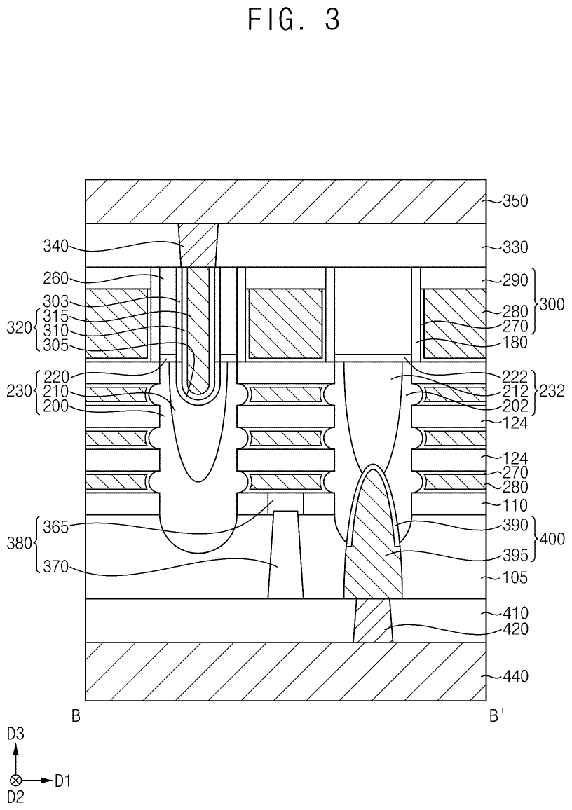

FIGS. 1 to 3 are a plan view and cross-sectional views illustrating a semiconductor device in accordance with example embodiments of the present inventive concept. Specifically, FIG. 1 is the plan view, and FIGS. 2 to 3 are the cross-sectional views. FIG. 2 is a cross-sectional view taken along line A-A′ of FIG. 1, and FIG. 3 is a cross-sectional view taken along line B-B′ of FIG. 1.

Referring to FIGS. 1 to 3, the semiconductor device may include a gate structure 300, semiconductor patterns 124, first and second source/drain layers 230 and 232, an etch stop pattern 110, a division structure 380, first and second contact plugs 320 and 400, a liner pattern 303, first and second vias 340 and 420, and first and second wirings 350 and 440.

The semiconductor device may further include an active pattern 105, an isolation pattern 130, a gate spacer 180, first to third insulating interlayers 260, 330 and 345, and fifth and sixth insulating interlayers 410 and 430.

The sixth insulating interlayer 430 and the fifth insulating interlayer 410 may be sequentially stacked upwardly in the third direction D3. In example embodiments of the present inventive concept, each of the fifth and sixth insulating interlayers 410, 430 may include an insulating material, e.g., silicon oxycarbide (SiOC), silicon oxide (SiO₂), silicon nitride (SiN), silicon oxynitride (SiON), silicon carbonitride (SiCN), silicon oxycarbonitride (SiOCN), etc.

The second wiring 440 may extend through the sixth insulating interlayer 430. In example embodiments of the present inventive concept, the second wiring 440 may extend in the first direction D1, and a plurality of second wirings 440 may be spaced apart from each other in the second direction D2. The second wiring 440 may serve as a power rail of the semiconductor device.

The second via 420 may extend through the fifth insulating interlayer 410, and may be disposed on an upper surface of the second wiring 440. For example, the second via 420 may contact the upper surface of the second wiring 440. In an embodiment of the present inventive concept, a plurality of the second vias 420 may be spaced apart from each other in the first direction D1 on each of the second wirings 440. For example, the plurality of second vias 420 may correspond with the second wirings 440, respectively.

Each of the second wiring 440 and the second via 420 may include a conductive material, e.g., a metal, a metal nitride, a metal silicide, etc.

The active pattern 105 may be disposed on the fifth insulating interlayer 410, and a sidewall of the active pattern 105 may be covered by the isolation pattern 130.

In example embodiments of the present inventive concept, the active pattern 105 may extend in the first direction D1, and a plurality of active patterns 105 may be spaced apart from each other in the second direction D2.

In example embodiments of the present inventive concept, the isolation pattern 130 may be disposed between neighboring ones of the active patterns 105 in the second direction D2, and the plurality of isolation patterns 130 may be spaced apart from each other in the second direction D2. For example, the isolation patterns 130 may extend in the first direction D1.

The active pattern 105 may include a semiconductor material, e.g., silicon, germanium, silicon-germanium, etc., or III-V semiconductor compounds, e.g., GaP, GaAs, GaSb, etc., and the isolation pattern 130 may include an oxide, e.g., silicon oxide.

In example embodiments of the present inventive concept, a plurality of semiconductor patterns 124 may be formed at a plurality of levels, respectively, and may be spaced apart from each other in the third direction D3 from an upper surface of the active pattern 105. Each of the plurality of semiconductor patterns 124 may extend in the first direction D1 to a given length. FIGS. 2 and 3 show three semiconductor patterns 124 at three levels, respectively, however, the present inventive concept is not limited thereto.

Additionally, FIG. 3 shows three semiconductor patterns 124 that are spaced apart from each other in the first direction D1 at each level on the active pattern 105 extending in the first direction D1; however, present the inventive concept is not limited thereto.

In example embodiments of the present inventive concept, the semiconductor pattern 124 may be a nano-sheet or nano-wire including a semiconductor material, e.g., silicon, germanium, etc. In example embodiments of the present inventive concept, the semiconductor pattern 124 may serve as a channel in a transistor, and thus may also be referred to as a channel.

The gate structure 300 may extend in the second direction D2 on the active pattern 105 and the isolation pattern 130, and may include a gate insulation pattern 270, a gate electrode 280 and a gate capping pattern 290.

In example embodiments of the present inventive concept, the gate structure 300 may at least partially surround a central portion in the first direction D1 of each of the semiconductor patterns 124, and may cover lower and upper surfaces and opposite sidewalls in the second direction D2 of each of the semiconductor patterns 124. For example, the gate structure 300 may completely surround the semiconductor patterns 124.

In example embodiments of the present inventive concept, the gate insulation pattern 270 may be disposed on a surface of each of the semiconductor patterns 124, an upper surface of the etch stop pattern 110, an upper surface of the isolation pattern 130, a portion of a sidewall each of the first and second source/drain layers 230 and 232 and an inner sidewall of the gate spacer 180. The gate electrode 280 may fill a space between the semiconductor patterns 124 that are spaced apart from each other in the third direction D3, a space between the active pattern 105 and a lowermost one of the semiconductor patterns 124, and a space between the gate spacers 180 that are spaced apart from each other in the first direction D1 on an uppermost one of the semiconductor patterns 124. The gate capping pattern 290 may be disposed on upper surfaces of the gate insulation pattern 270 and the gate electrode 280, and the inner sidewall of the gate spacer 180. For example, the gate capping pattern 290 may contact upper surfaces of the gate insulation pattern 270 and the gate electrode 280 and the inner sidewall of the gate spacer 180.

Hereinafter, a portion of the gate structure 300 on the uppermost one of the semiconductor patterns 124 may be referred to as an upper portion, and a portion of the gate structure 300 below the upper portion may be referred to as a lower portion.

The gate insulation pattern 270 may include an oxide, e.g., silicon oxide. The gate electrode 280 may include a metal nitride, e.g., titanium nitride (TiN), titanium aluminum nitride (TiAIN), tantalum nitride (TaN), tantalum aluminum nitride (TaAIN), etc., a metal alloy, a metal carbide, a metal oxynitride, a metal carbonitride or a metal oxycarbonitride, e.g., titanium aluminum carbide (TiAIC), titanium aluminum oxynitride (TiAION), titanium aluminum carbonitride (TiAICN), titanium aluminum oxycarbonitride (TiAIOCN), etc., or a low-resistance metal, e.g., tungsten (W), aluminum (Al), copper (Cu), or tantalum (Ta). The gate capping pattern 290 may include an insulating nitride, e.g., silicon nitride.

The gate spacer 180 may be formed on each of opposite sidewalls in the first direction D1 of the upper portion of the gate structure 300. The gate spacer 180 may include an oxide, e.g., silicon oxide, or an insulating nitride, e.g., silicon nitride. The gate capping pattern 290 may include an insulating nitride, e.g., silicon nitride.

The first and second source/drain layers 230 and 232 may be disposed at opposite sides, respectively, of the gate structure 300 on the active pattern 105. Each of the first and second source/drain layers 230 and 232 may contact a sidewall in the first direction D1 of the lower portion of the gate structure 300, sidewalls of the semiconductor patterns 124 in the first direction D1 and a sidewall of the etch stop pattern 110 in the first direction D1.

The first source/drain layer 230 may include a first epitaxial pattern 210, a second epitaxial pattern 200 and a first capping pattern 220. The second source/drain layer 232 may include a third epitaxial pattern 212, a fourth epitaxial pattern 202 and a second capping pattern 222.

In example embodiment of the present inventive concept, each of the first and third epitaxial patterns 210 and 212 may have a pillar shape extending in the third direction D3, and a sidewall and a lower surface of each of the first and third epitaxial patterns 210 and 212 may be covered by the second and fourth epitaxial patterns 200 and 202, respectively.

In example embodiments of the present inventive concept, each of the second and fourth epitaxial patterns 200 and 202 may extend in the third direction D3, and an outer sidewall of each of the second and fourth epitaxial patterns 200 and 202 may have a protrusion portion protruding in the first direction D1 towards the gate structure 300.

That is, a portion of the gate structure 300 between the semiconductor patterns 124, which are spaced apart from each other in the third direction D3, may have a width in the first direction D1 smaller than a width in the first direction D1 of the semiconductor patterns 124. A sidewall in the first direction D1 of the portion of the gate structure 300 may have a concave shape compared to the sidewalls in the first direction D1 of the semiconductor patterns 124, which may be disposed above and below of the portion of the gate structure 300, respectively. The protrusion portion of each of the second and fourth epitaxial patterns 200 and 202 may protrude towards the concave sidewall of the portion of the gate structure 300, and as the plurality of semiconductor patterns 124 are spaced apart from each other in the third direction D3, a plurality of protrusion portions may be spaced apart from each other in the third direction D3, correspondingly.

In example embodiments of the present inventive concept, each of the first and third epitaxial patterns 210 and 212 may include single-crystal silicon (Si) doped with n-type impurities, e.g., arsenic (As), phosphorus (P), etc., and each of the second and fourth epitaxial patterns 200 and 202 may include single-crystal silicon (Si) or single-crystal silicon (Si) doped with n-type impurities, e.g., arsenic (As), phosphorus (P), etc. A concentration of the n-type impurities doped in the silicon (Si) in each of the first and third epitaxial patterns 210 and 212 may be higher than a concentration of the n-type impurities doped in the silicon (Si) in each of the second and fourth epitaxial patterns 200 and 202.

That is, the first and second epitaxial patterns 210 and 200 and the third and fourth epitaxial patterns 212 and 202 in the first and second source/drain layers 230 and 232, respectively, may be doped with the n-type impurities, and thus, each of the first and second source/drain layers 230 and 232 may serve as a source/drain of a NMOS transistor. In this case, each of the first and second source/drain layers 230 and 232 may have a cross-section taken along the second direction D2, which may have a shape of, e.g., a rectangle with rounded corners or a circle.

In embodiments of the present inventive concept, each of the first and third epitaxial patterns 210 and 212 may include single-crystal silicon-germanium (Si—Ge) doped with p-type impurities, e.g., boron (B), gallium (Ga), etc., and each of the second and fourth epitaxial patterns 200 and 202 may include single-crystal silicon-germanium (Si—Ge) or single-crystal silicon-germanium (Si—Ge) doped with p-type impurities, e.g., boron (B), gallium (Ga), etc. A concentration of the p-type impurities doped in the silicon-germanium (Si—Ge) in each of the first and third epitaxial patterns 210 and 212 may be higher than a concentration of the p-type impurities doped in the silicon-germanium (Si—Ge) in each of the second and fourth epitaxial patterns 200 and 202.

That is, the first and second epitaxial patterns 210 and 200 and the third and fourth epitaxial patterns 212 and 202 in the first and second source/drain layers 230 and 232, respectively, may be doped with the p-type impurities, and thus, each of the first and second source/drain layers 230 and 232 may serve as a source/drain of a PMOS transistor. In this case, each of the first and second source/drain layers 230 and 232 may have a cross-section taken along the second direction D2, which may have, e.g., a shape of a pentagon.

The etch stop pattern 110 may be disposed between the gate structure 300 and the active pattern 105. For example, the upper surface of the etch stop pattern 110 may contact the gate insulation pattern 270 that is in the gate structure 300, and each of opposite sidewalls in the first direction D1 of the etch stop pattern 110 may contact the first and second source/drain layers 230 and 232, respectively. For example, a lower surface of the etch stop pattern 110 may contact the upper surface of the active pattern 105.

In example embodiments of the present inventive concept, the etch stop pattern 110 may overlap with corresponding ones of the semiconductor patterns 124 in the third direction D3, and a plurality of etch stop patterns 110 may be spaced apart from each other in the first and second directions D1 and D2.

In example embodiments of the present inventive concept, the etch stop pattern 110 may include, e.g., silicon doped with one of oxygen, nitrogen, fluorine, silicon germanium, silicon-germanium doped with one of oxygen, nitrogen, fluorine, silicon germanium, or silicon-germanium doped with carbon, etc.

The division structure 380 may be disposed between the first and second source/drain layers 230 and 232 that neighbor each other in the first direction D1, and may include a first division pattern 365 and a second division pattern 370. For example, the division structure 380 may create an electrical barrier between the first and second source/drain layers 230 and 232.

The first division pattern 365 may be disposed in a central portion of the etch stop pattern 110 that is disposed between the first and second source/drain layers 230 and 232. In example embodiments of the present inventive concept, the first division pattern 365 may divide the etch stop pattern 110. In example embodiments of the present inventive concept, a height of an upper surface of the first division pattern 365 may be substantially the same as a height of the upper surface of the etch stop pattern 110, and a height of a lowermost surface of the first division pattern 365 may be substantially the same as a height of a lower surface of the etch stop pattern 110. In example embodiments of the present inventive concept, the first division pattern 365 may have a thickness that is substantially the same as a thickness of the etch stop pattern 110.

In example embodiments of the present inventive concept, the upper surface and an upper portion of each of opposite sidewalls in the second direction D2 of the first division pattern 365 may contact a central portion of the gate structure 300 in the first direction D1, for example, the gate insulation pattern 270 of the gate structure 300. For example, the gate insulation pattern 270 may be disposed on an upper surface and sidewalls of the first division pattern 365. For example, each of opposite sidewalls in the first direction D1 of the first division pattern 365 may contact a sidewall of the etch stop pattern 110, and a portion of each of opposite sidewalls in the second direction D2 of the first division pattern 365 may contact an upper sidewall of the isolation pattern 130. For example, a lower portion of each of opposite sidewalls of the first division pattern 365 may contact the upper sidewall of the isolation pattern 130.

FIG. 3 shows that each of the opposite sidewalls of the first division pattern 365 in the first direction D1 has a vertical slope; however, the present inventive concept is not limited thereto, and the opposite sidewalls of the first division pattern 365 may have a convex shape toward the first and second source/drain layers 230 and 232 adjacent thereto, respectively.

The second division pattern 370 may be disposed on the fifth insulating interlayer 410, and may extend through the active pattern 105 to contact a lower portion of the first division pattern 365. In an example embodiment of the present inventive concept, the second division pattern 370 may extend partially through the lower portion of the first division pattern 365, and thus may have an upper surface higher than the lowermost surface of the first division pattern 365. In an example embodiment of the present inventive concept, a width of the second division pattern 370 may increase from an upper surface to a lower surface thereof in the third direction D3. For example, the second division pattern 370 may have a tapered shape. For example, the second division pattern 370 has an upper surface that is narrower than a lower surface of the first division pattern 365.

In example embodiments of the present inventive concept, the first division pattern 365 may include, e.g., silicon oxide, silicon nitride, silicon-germanium oxide, or silicon-germanium nitride, and the second division pattern 370 may include, e.g., a low-k material.

The first contact plug 320 may be disposed on the first source/drain layer 230. For example, the first contact plug 320 may extend through the first insulating interlayer 260, the first capping pattern 220 and an upper portion of the first epitaxial pattern 210, and may contact the upper portion of the first epitaxial pattern 210. The first contact plug 320 may include a first ohmic contact pattern 305, a barrier pattern 310 and a first conductive pattern 315 sequentially stacked.

The first conductive pattern 315 may have a pillar shape extending in the third direction D3, and the barrier pattern 310 may cover a sidewall and a lower surface of the first conductive pattern 315. The first ohmic contact pattern 305 may cover a lower portion of a sidewall and a lower surface of the barrier pattern 310, and may contact the first epitaxial pattern 210.

The liner pattern 303 may be disposed on the first ohmic contact pattern 305 and cover an outer sidewall of an upper portion of the barrier pattern 310, and an outer sidewall of the liner pattern 303 may be covered by the first insulating interlayer 260. In example embodiments of the present inventive concept, the liner pattern 303 may include an insulating material, e.g., silicon carbonate (SiOC), silicon oxide (SiO₂) or silicon nitride (SiN).

The second contact plug 400 may be disposed beneath the second source/drain layer 232, and may include a second ohmic contact pattern 390 and a second conductive pattern 395 sequentially stacked. For example, the second ohmic contact pattern 390 may be disposed on the second conductive pattern 395.

The second conductive pattern 395 may include a lower portion, which may include a sidewall covered by the active pattern 105 and an upper portion, which may include a sidewall and an upper surface, covered by the second ohmic contact pattern 390. An upper portion of the second ohmic contact pattern 390 may contact the third epitaxial pattern 212, and a lower portion of the second ohmic contact pattern 390 may contact the fourth epitaxial pattern 202.

In example embodiments of the present inventive concept, each of the first and second ohmic contact patterns 305 and 390 may include, e.g., a metal silicide, each of the first and second conductive patterns 315 and 395 may include a low-resistivity metal, e.g., tungsten (W), titanium (Ti), etc., and the barrier pattern 310 may include a metal nitride, e.g., titanium nitride (TiN).

The first to third insulating interlayers 260, 330 and 345 may be sequentially stacked on the active pattern 105 and the isolation pattern 130 in the third direction D3.

The first insulating interlayer 260 may be disposed on the active pattern 105 and the isolation pattern 130, and may cover the first and second source/drain layers 230 and 232. The first insulating interlayer 260 may at least partially surround the gate spacer 180 on a sidewall of the gate structure 300. The second insulating interlayer 330 may be disposed on the first insulating interlayer 260, the gate structure 300, the gate spacer 180 and the first contact plug 320. The third insulating interlayer 345 may be disposed on the second insulating interlayer 330.

Each of the first to third insulating interlayers 260, 330 and 345 may include insulating materials, e.g., silicon oxycarbide (SiOC), silicon oxide (SiO₂), silicon nitride (SiN), silicon oxynitride (SiON), silicon carbonitride (SiCN), silicon oxycarbonitride (SiOCN), etc.

The first via 340 may extend through the second insulating interlayer 330, and may be disposed on an upper surface of the first contact plug 320. For example, the first via 340 may contact the upper surface of the first contact plug 320. The first wiring 350 may extend through the third insulating interlayer 345, and may be disposed on an upper surface of the first via 340. For example, the first wiring 350 may contact the upper surface of the first via 340.

The first wiring 350 may extend in the first direction D1, and a plurality of first wirings 350 may be spaced apart from each other in the second direction D2. Each of the first wiring 350 and the first via 340 may include, e.g., a metal and/or a metal nitride.

The semiconductor device may be a multi-bridge channel field effect transistor (MBCFET) including the semiconductor patterns 124 that are spaced apart from each other in the third direction D3 and serving as channels, respectively.

As illustrated above, the division structure 380 may extend through a portion of the active pattern 105 between the first and second source/drain layers 230 and 232, and may contact the lower surface of the gate structure 300. The division structure 380 may include the first division pattern 365, which contacts the lower surface of the gate structure 300, and the second division pattern 370, which extends through and contacts the lower portion of the first division pattern 365. The first division pattern 365 may include an oxide or a nitride, and the second division pattern 370 may include a low-k material, so that the division structure 380 may prevent leakage current between the first and second source/drain layers 230 and 232.

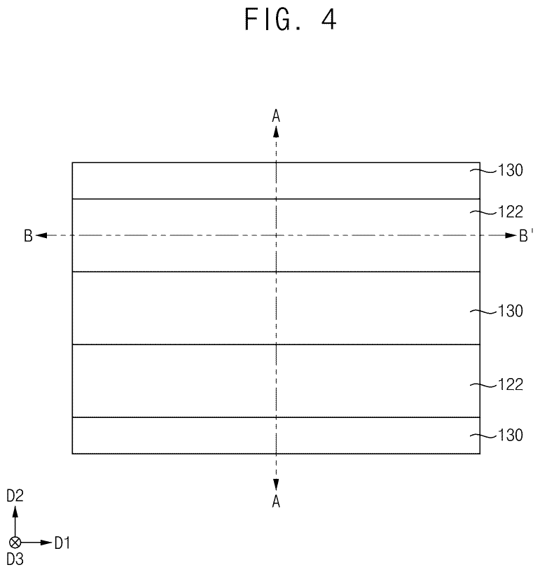

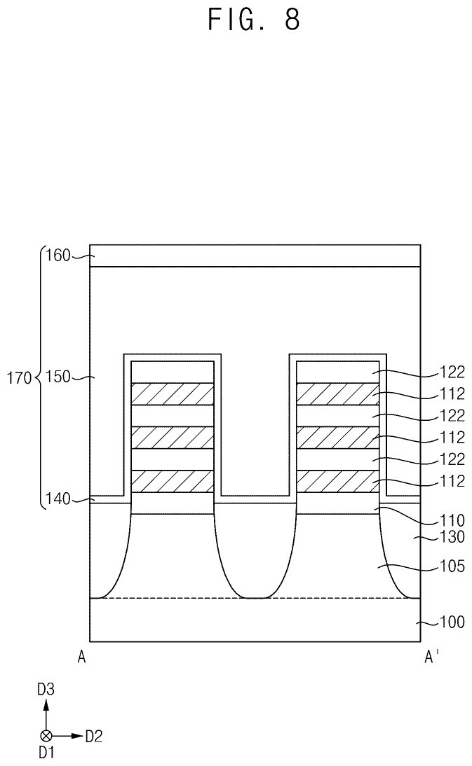

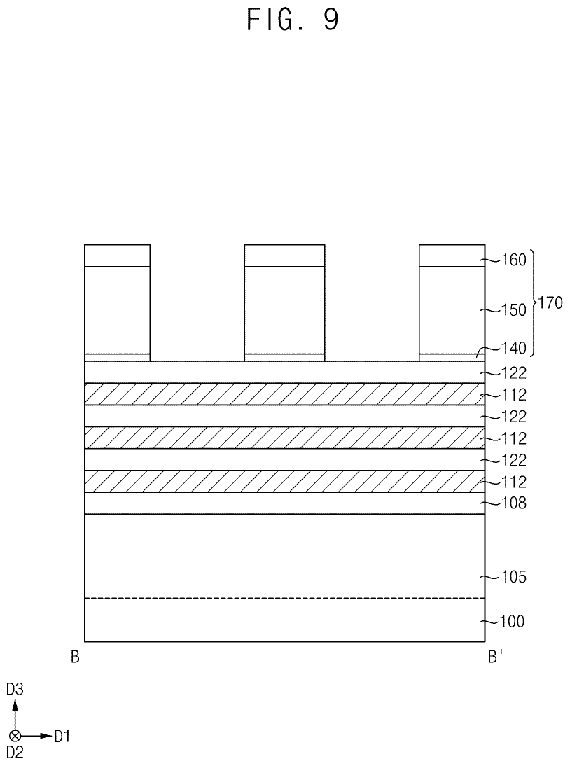

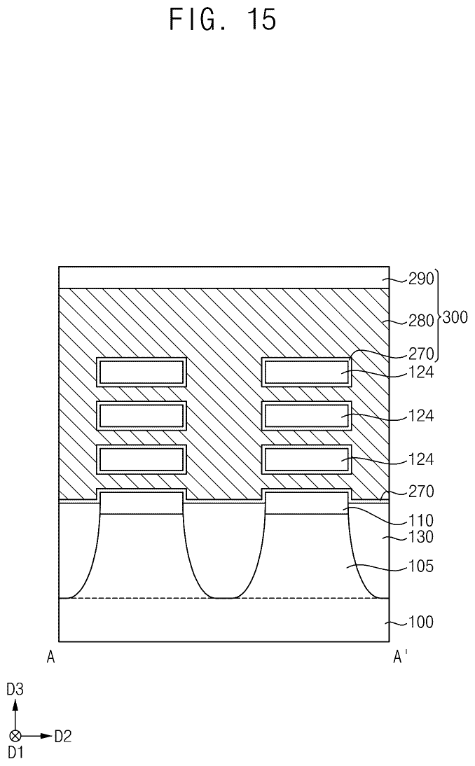

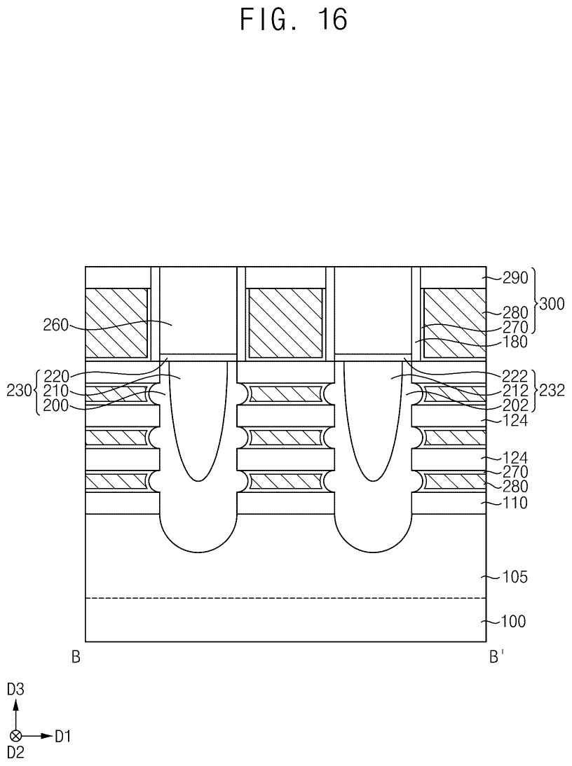

As illustrated below with reference to FIGS. 4 to 23, the division structure 380 may be disposed in an opening, which is formed by an etching process, extending through the active pattern 105. During the etching process, the etch stop pattern 110 may be disposed on the gate structure 300, and may prevent the gate structure 300 from being damaged during the etching process. Thus, the semiconductor device including the gate structure 300 may have improved electrical characteristics by preventing damage to the gate structure 300.

FIGS. 4 to 23 are plan views and cross-sectional views illustrating a semiconductor device in accordance with example embodiments of the present inventive concept.

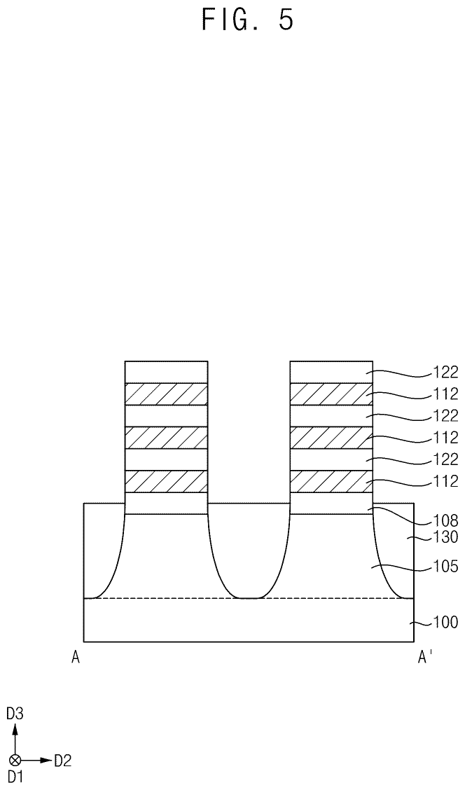

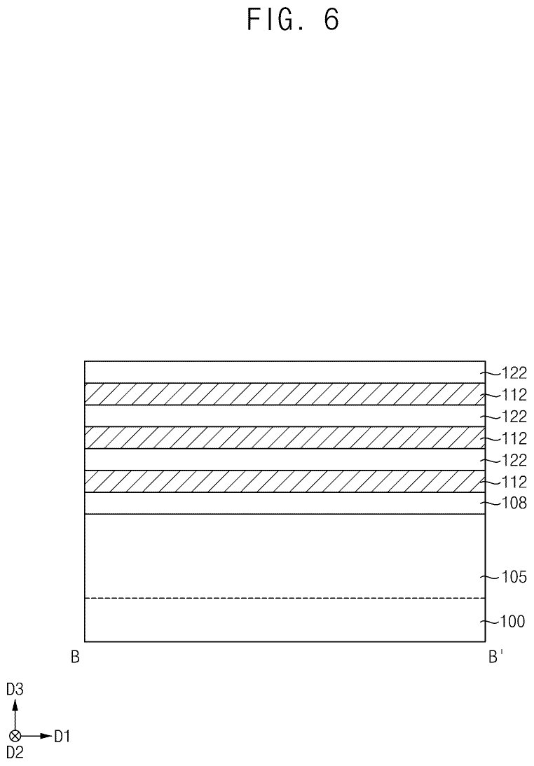

Particularly, FIGS. 4, 7, 10 and 14 are the plan views, and FIGS. 5-6, 8-9, 11-13 and 15-23 are the cross-sectional views. FIGS. 5, 8 and 15 are cross-sectional views taken along lines A-A′ of corresponding plan views, respectively, FIGS. 6, 9, 11-13 and 16-23 are cross-sectional views taken along lines B-B′ of corresponding plan views, respectively.

Referring to FIGS. 4 to 6, an etch stop layer may be formed on a substrate 100, a sacrificial layer and a semiconductor layer may be alternately and repeatedly stacked on the etch stop layer, a first etching mask extending in the first direction D1 may be formed on an uppermost one of the semiconductor layers, and the semiconductor layers, the sacrificial layers and an upper portion of the substrate 100 may be etched using the first etching mask.

Thus, an active pattern 105 extending in the first direction D1 may be formed on the substrate 100, and a fin structure including the etch stop line 108, and sacrificial lines 112 and semiconductor lines 122, which may be alternately and repeatedly stacked in the third direction D3 on the etch stop line 108, may be formed on the active pattern 105. In example embodiments of the present inventive concept, the fin structure may extend in the first direction D1, and a plurality of fin structures may be spaced apart from each other in the second direction D2 on the substrate 100.

FIGS. 5 and 6 show three sacrificial lines 112 and three semiconductor lines 122 at three levels, respectively; however, the present inventive concept is not limited thereto. The etch stop line 108 may include, e.g., silicon or silicon-germanium doped with impurities, the semiconductor lines 122 may include, e.g., silicon, and the sacrificial lines 112 may include a material having an etching selectivity with respect to the substrate 100 and the semiconductor lines 122, e.g., silicon-germanium.

An isolation pattern 130 may be formed on the substrate 100 to cover a sidewall of the active pattern 105.

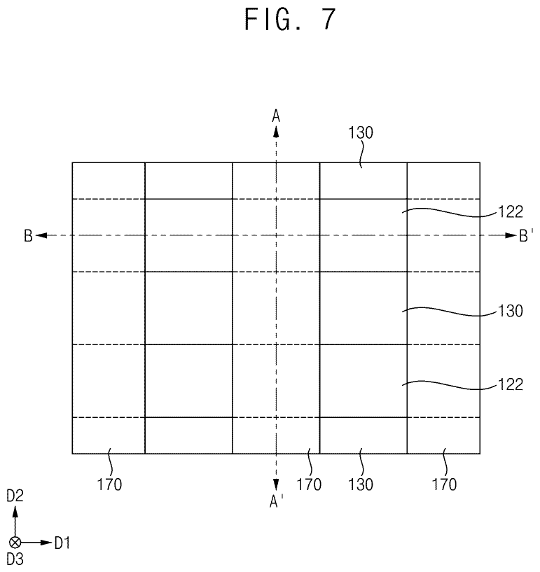

Referring to FIGS. 7 to 9, a dummy gate insulation layer, a dummy gate electrode layer and a dummy gate mask layer may be sequentially formed on the substrate 100 to cover the fin structure and the isolation pattern 130, a second etching mask extending in the second direction D2 may be formed on the dummy gate mask layer, and the dummy gate mask layer may be etched by using the second etching mask to form a dummy gate mask 160 on the substrate 100.

The dummy gate electrode layer and the dummy gate insulation layer may be etched by using the dummy gate mask 160 as an etching mask to form a dummy gate electrode 150 and a dummy gate insulation pattern 140, respectively, on the substrate 100.

The dummy gate insulation pattern 140, the dummy gate electrode 150 and the dummy gate mask 160 sequentially stacked in the third direction D3 on the active pattern 105 and a portion of the isolation pattern 530 adjacent thereto may collectively form a dummy gate structure 170.

In example embodiments of the present inventive concept, the dummy gate structure 170 may extend in the second direction D2 on the fin structure and the isolation pattern 130, and may cover an upper surface and opposite sidewalls in the second direction D2 of the fin structure.

In example embodiments of the present inventive concept, a plurality of dummy gate structures 170 may be spaced apart from each other in the first direction D1.

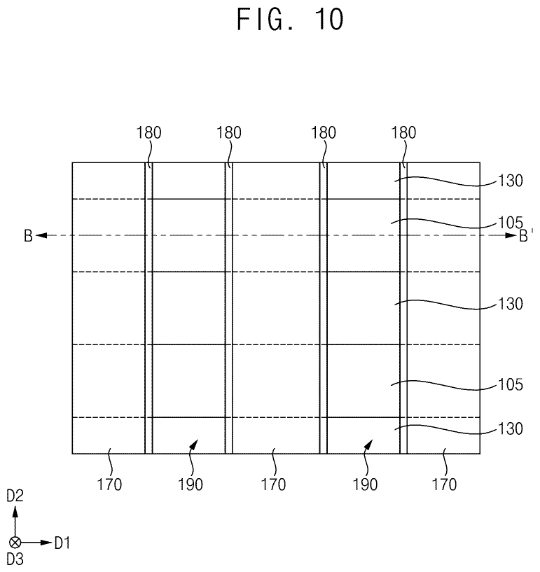

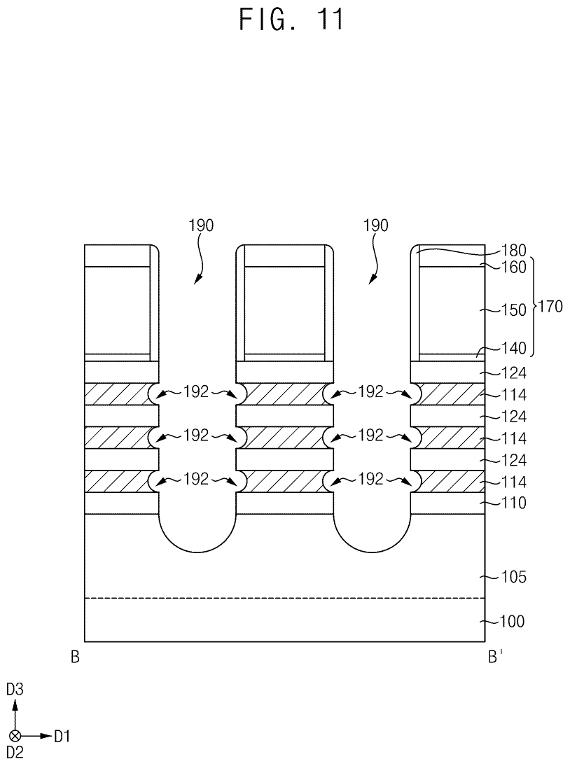

Referring to FIGS. 10 and 11, a gate spacer 180 may be formed on a sidewall of the dummy gate structure 170.

For example, a gate spacer layer may be formed on the substrate 100 having the fin structure, the isolation pattern 130 and the dummy gate structure 170 thereon, and may be anisotropically etched to form the gate spacer 180 covering each of opposite sidewalls in the first direction D1 of the dummy gate structure 170.

The fin structure and an upper portion of the active pattern 105 may be etched by using the dummy gate structure 170 and the gate spacer 180 as an etching mask to form a first opening 190.

Thus, the etch stop line 108, the sacrificial lines 112 and the semiconductor lines 122 under the dummy gate structure 170 and the gate spacer 180 may be transformed into an etch stop pattern 110, sacrificial patterns 114 and semiconductor patterns 124, respectively, and the fin structure extending in the first direction D1 may be divided into a plurality of parts spaced apart from each other in the first direction D1.

Hereinafter, the dummy gate structure 170, the gate spacer 180 on each of opposite sidewalls of the dummy gate structure 170 and the fin structure may collectively be referred to as a stack structure. In example embodiments of the present inventive concept, the stack structure may extend in the second direction D2, and a plurality of stack structures may be spaced apart from each other in the first direction D1.

A first recess 192 may be formed by etching each of opposite sidewalls in the first direction D1 of the sacrificial patterns 114 exposed by the first opening 190. In example embodiments of the present inventive concept, the first recess 192 may be formed by performing a wet etching process on the sacrificial patterns 114.

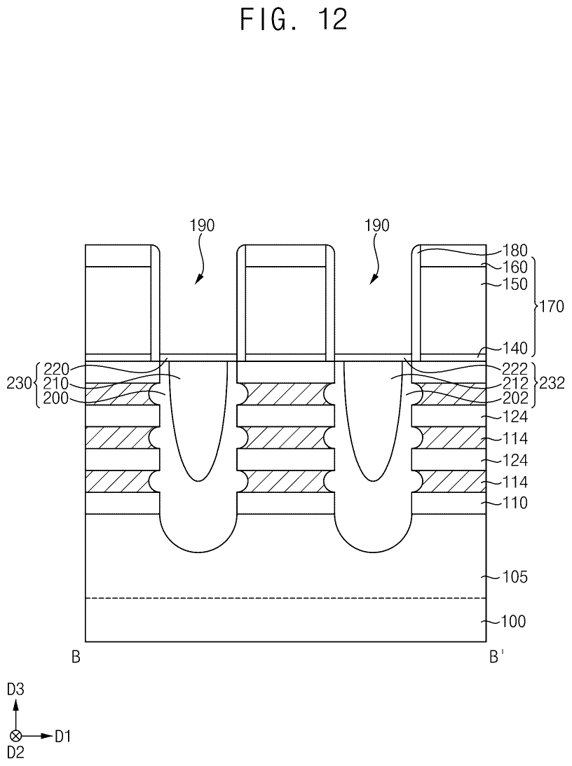

Referring to FIG. 12, a first selective epitaxial growth (SEG) process may be performed using an upper surface of the active pattern 105 and sidewalls of the etch stop pattern 110, the semiconductor patterns 124 and the sacrificial patterns 114 exposed by the first opening 190 as a seed to form an epitaxial pattern on the upper surface of the active pattern 105 between sidewalls facing each other in the first direction D1 of the stack structures neighboring in the first direction D1, and the sidewalls of the etch stop pattern 110, the semiconductor patterns 124 and the sacrificial patterns 114.

Hereinafter, the epitaxial pattern on a first sidewall of opposite sidewalls in the first direction D1 of the stack structure may be referred to as a second epitaxial pattern 200, and the epitaxial pattern on a second sidewall of opposite sidewalls in the first direction D1 may be referred to as a fourth epitaxial pattern 202.

In example embodiments of the present inventive concept, the first SEG process may be performed using a silicon source gas, e.g., disilane (Si₂H₆) gas, SiH₄ gas, SiCl₂H₂ gas, SiHCl₃ gas and SiH₃CH₃ gas, etc., and an etching gas, e.g., HCl, Cl₂. The first SEG process may be performed using a source gas including n-type impurities, e.g., arsenic (As) or phosphorus (P), together with the silicon source gas and the etching gas, and thus each of the second and fourth epitaxial patterns 200 and 202 may include single crystal silicon or silicon doped with n-type impurities.

In embodiments of the present inventive concept, the first SEG process may be performed using a silicon source gas, e.g., disilane (Si₂H₆) gas, SiH₄ gas, SiCl₂H₂ gas, SiHCl₃ gas and SiH₃CH₃ gas, etc., and a germanium source gas, e.g., GeH₄. The first SEG process may be performed using a source gas including p-type impurities, e.g., diborane (B₂H₆) gas, together with the silicon source gas and the germanium source gas, and thus each of the second and fourth epitaxial patterns 200 and 202 may include single crystal silicon-germanium or silicon-germanium doped with p-type impurities.

A second SEG process may be performed using a surface of each of the second and fourth epitaxial patterns 200 and 202 as a seed to form first and third epitaxial patterns 210 and 212 on the second and fourth epitaxial patterns 200 and 202, respectively, filling a lower portion of the first openings 190.

In example embodiments of the present inventive concept, the second SEG process may be performed using a silicon source gas, e.g., disilane (Si₂H₆) gas, SiH₄ gas, SiCl₂H₂ gas, SiHCl₃ gas and SiH₃CH₃ gas, etc., and an etching gas, e.g., HCl, Cl₂, and a source gas including n-type impurities, e.g., arsenic (As) or phosphorus (P), and thus each of the first and third epitaxial patterns 210 and 212 may include silicon doped with n-type impurities.

In embodiments of the present inventive concept, the second SEG process may be performed using a silicon source gas, e.g., disilane (Si₂H₆) gas, SiH₄ gas, SiCl₂H₂ gas, SiHCl₃ gas and SiH₃CH₃ gas, etc., and a germanium source gas, e.g., GeH₄ and a source gas including p-type impurities, e.g., diborane (B₂H₆) gas, and thus each of the first and third epitaxial patterns 210 and 212 may include silicon-germanium doped with p-type impurities.

A third SEG process may be performed to form a first capping pattern 220 on the first and second epitaxial patterns 210 and 200 and to form a second capping pattern 222 on the third and fourth epitaxial patterns 212 and 202.

The first and second epitaxial patterns 210 and 200 and the first capping pattern 220 may collectively form a first source/drain layer 230. The third and fourth epitaxial patterns 212 and 202 and the second capping pattern 222 may collectively form a second source/drain layer 232.

In example embodiments of the present inventive concept, each of the first and second source/drain layer 230 and 232 may have a cross-section taken along the second direction D2, which may have a pentagon-like shape. In embodiments of the present inventive concept, each of the first and second source/drain layer 230 and 232 may have a cross-section taken along the second direction D2, which may have a square with rounded corners or a circle shape.

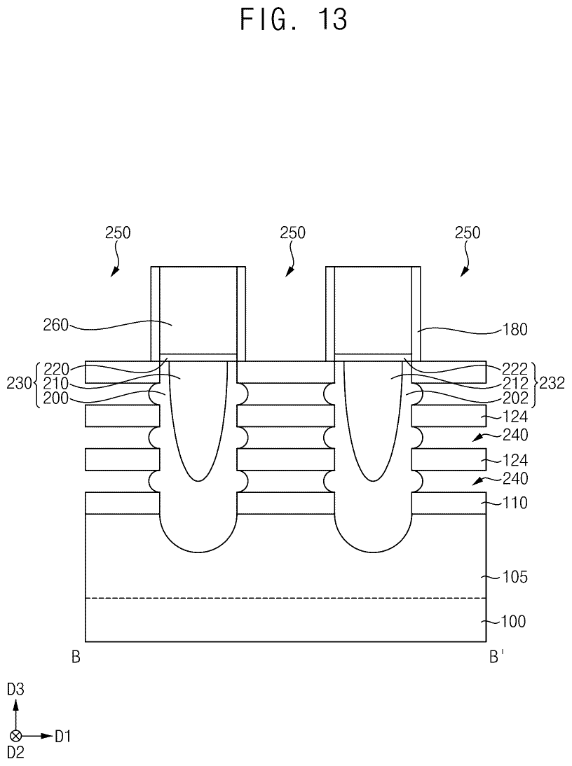

Referring to FIG. 13, a first insulating interlayer 260 may be formed on the stack structure, the first and second source/drain layers 230 and 232 and the isolation pattern 130, and a planarization process may be performed until an upper surface of the dummy gate electrode 150 in the stack structure is exposed to remove an upper portion of the first insulating interlayer 260 and the dummy gate mask 160 in the dummy gate structure 170.

The exposed dummy gate electrode 150, and the dummy gate insulation pattern 140 and the sacrificial patterns 114 under the dummy gate electrode 150 may be removed by performing, e.g., a wet etching process and/or a dry etching process.

Thus, a second opening 240 exposing surfaces of the semiconductor patterns 124, an upper surface of the etching stop pattern 110 and an upper surface of the isolation pattern 130 may be formed, and a third opening 250 exposing an inner sidewall of the gate spacer 180 and an upper surface of an uppermost one of the semiconductor patterns 124 may be formed. For example, the second opening 240 may be disposed between the semiconductor patterns 124.

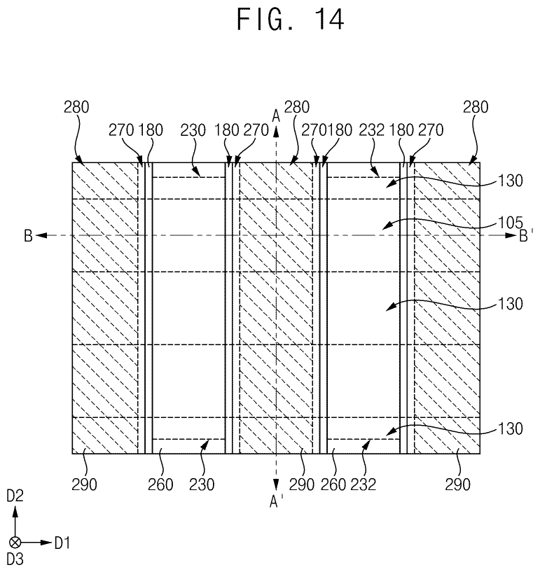

Referring to FIGS. 14 to 16, a gate insulation layer may be formed on the inner sidewall of the gate spacer 180, the surfaces of the semiconductor patterns 124, the upper surface of the etch stop pattern 110, the upper surface of isolation pattern 130 exposed by the second and third openings 240 and 250, and an upper surface of first insulating interlayer 260, and a gate electrode layer may be formed to fill a remaining portion of the second and third openings 240 and 250 on the gate insulation layer.

A planarization process may be performed on the gate electrode layer and the gate insulation layer until the upper surface of the first insulating interlayer 260 is exposed, and thus, a gate electrode 280 and a gate insulation pattern 270 may be formed in the second and third openings 240 and 250.

Upper portions of the gate insulation pattern 270 and the gate electrode 280 may be removed to form a second recess, and a gate capping pattern 290 may be formed in the second recess. Thus, a gate structure 300 including the gate insulation pattern 270, the gate electrode 280 and the gate capping pattern 290 may be formed.

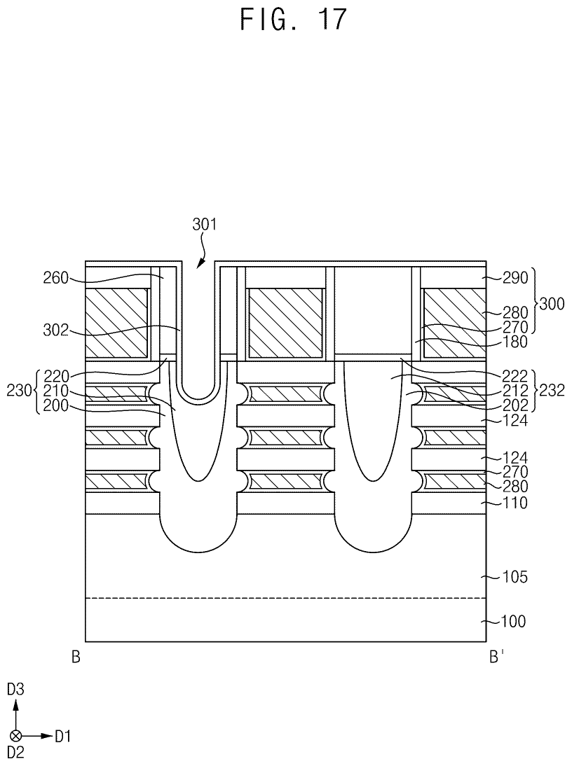

Referring to FIG. 17, a fourth opening 301 may be formed to extend through the first insulating interlayer 260, the first capping pattern 220 and an upper portion of the first epitaxial pattern 210.

A liner 302 may be formed on a sidewall of the first insulating interlayer 260, a sidewall of the first capping pattern 220, an upper surface of the first epitaxial pattern 210 exposed by the fourth opening 301 and the upper surface of the first insulating interlayer 260, an upper surface of the gate structure 300 and an upper surface of the gate spacer 180.

In example embodiments of the present inventive concept, the liner 302 may be formed with a relatively thin thickness compared to a width of the fourth opening 301, so that the fourth opening 301 might not be completely filled by the liner 302.

An ion implantation process and an annealing process may be sequentially performed on the first source/drain layer 230 through the fourth opening 301.

In example embodiments of the present inventive concept, the ion implantation process may be performed using, e.g., n-type impurities such as phosphorus (P) and arsenic (As). In embodiments of the present inventive concept, the ion implantation process may be performed using, e.g., p-type impurities such as boron (B) and gallium (Ga).

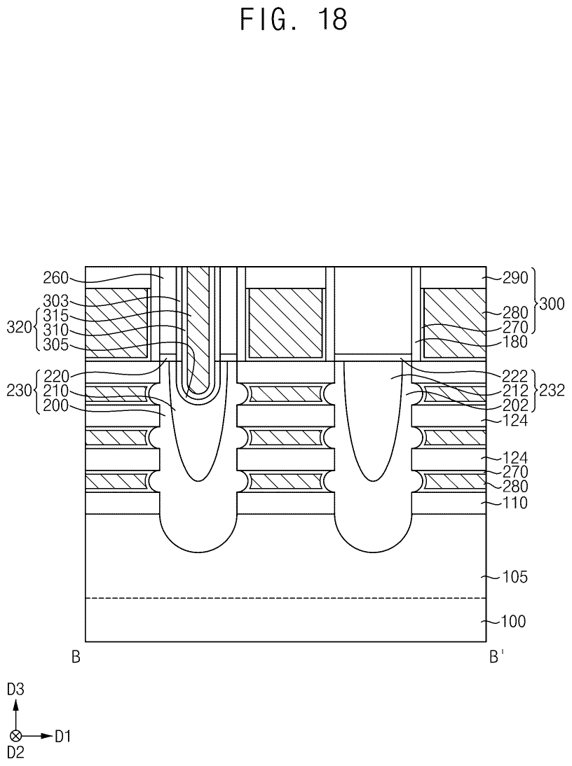

Referring to FIG. 18, a lower portion of the liner 302, that is, a portion of the liner 302 contacting the first source/drain layer 230, may be removed by a cleaning process by using, e.g., hydrogen fluoride (HF) or phosphoric acid (H₃PO₄) to expose an upper portion of the first source/drain layer 230, and, e.g., a selective deposition process may be performed on the upper portion of the exposed first source/drain layer 230 to form a first ohmic contact pattern 305.

A barrier layer and a first conductive layer may be formed on the liner 302 and the first ohmic contact pattern 305, and a planarization process may be performed on the barrier layer and the first conductive layer until the upper surfaces of the gate capping pattern 290, the gate spacer 180 and the first insulating interlayer 260 are exposed. Thus, the liner 302, the barrier layer and the first conductive layer may be transformed into the liner pattern 303, the barrier pattern 310 and the first conductive pattern 315, respectively.

The first ohmic contact pattern 305, the barrier pattern 310 and the first conductive pattern 315 may collectively form a first contact plug 320.

The planarization process may include, e.g., a chemical mechanical polishing (CMP) process and/or an etch back process.

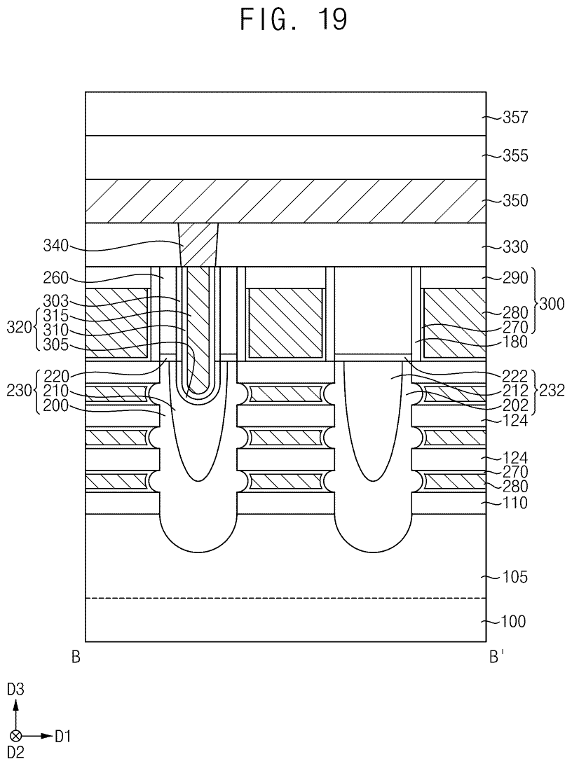

Referring to FIG. 19, a second insulating interlayer 330 may be formed on the first insulating interlayer 260, the first contact plug 320, the gate spacer 180 and the gate structure 300, an etching process may be performed thereon to partially remove the second insulating interlayer 330 to form a fifth opening that exposes an upper surface of the first contact plug 320, and a first via 340 may be formed to fill the fifth opening.

A third insulating interlayer 345 may be formed on the second insulating interlayer 330 and the first via 340, an etching process may be performed thereon to partially remove the third insulating interlayer 345 to form a sixth opening that exposes an upper surface of the first via 340, and a first wiring 350 may be formed to fill the sixth opening.

In example embodiments of the present inventive concept, the first wiring 350 may extend in the first direction D1 and a plurality of first wirings 350 may be spaced apart from each other in the second direction D2.

A fourth insulating interlayer 355 may be formed on a support substrate 357, and the fourth insulating interlayer 355 may be bonded to upper surfaces of the third insulating interlayer 345 and the first wiring 350.

In example embodiments of the present inventive concept, the support substrate 357 may include substantially the same material as the substrate 100.

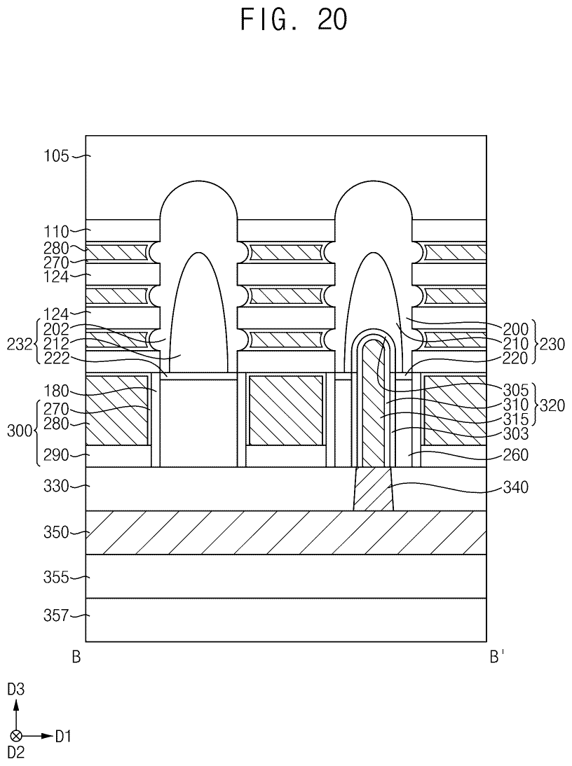

Referring to FIG. 20, the support substrate 357 may be flipped so that various structures on the substrate 100 may be flipped upside down, and hereinafter are illustrated based on the changed direction.

The substrate 100 may be removed by performing, e.g., a grinding process thereon, and thus the upper surface of the active pattern 105 may be exposed.

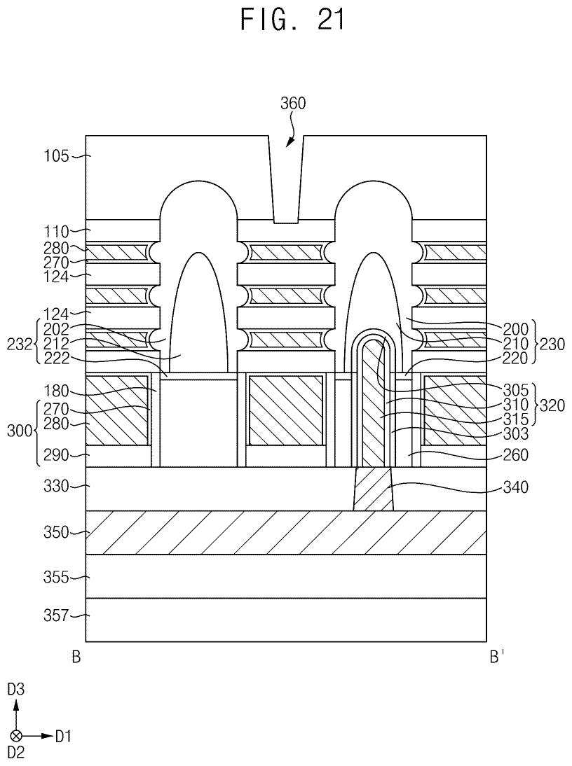

Referring to FIG. 21, a seventh opening 360 may be formed by performing, e.g., a dry etching process on a portion of the active pattern 105 that is between the first and second source/drain layers 230 and 232, and may extend through the portion of the active pattern 105 to expose an upper portion of the etch stop pattern 110.

In example embodiments of the present inventive concept, the seventh opening 360 may expose an upper surface of a central portion in the first direction D1 of a portion of the etch stop pattern 110 between the first and second source/drain layers 230 and 232, and may extend in the second direction D2 corresponding to the gate structure 300 extending in the second direction D2.

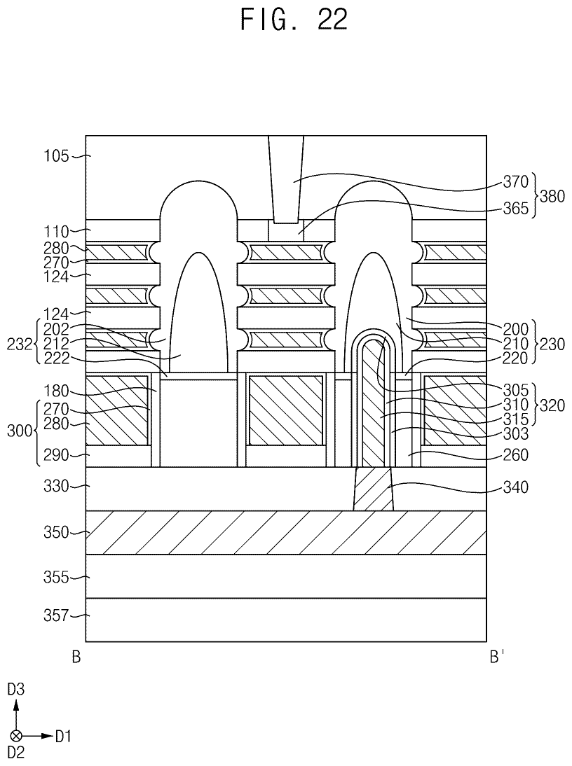

Referring to FIG. 22, a first division pattern 365 may be formed at a portion of the etch stop pattern 110 that is below the seventh opening 360.

In an embodiment of the present inventive concept, the first division pattern 365 may be formed by performing, e.g., a wet etching process on a portion of the etch stop pattern 110 that is exposed by the seventh opening 360 to form an eighth opening exposing a sidewall of the etch stop pattern 110 and an upper surface of the gate structure 300, and by performing, e.g., a deposition process to fill the eighth opening. For example, the eighth opening may penetrate the etch stop pattern 110.

In an embodiment of the present inventive concept, the first division pattern 365 may be formed by performing an oxidation process or a nitration process on the exposed portion of the etch stop pattern 110.

A second division layer may be formed on the active pattern 105 to fill the remaining portion of the seventh opening 360 by performing, e.g., a deposition process, and a planarization process may be performed thereon to form a second division pattern 370. The first division pattern 365 and the second division pattern 370 may collectively form a division structure 380.

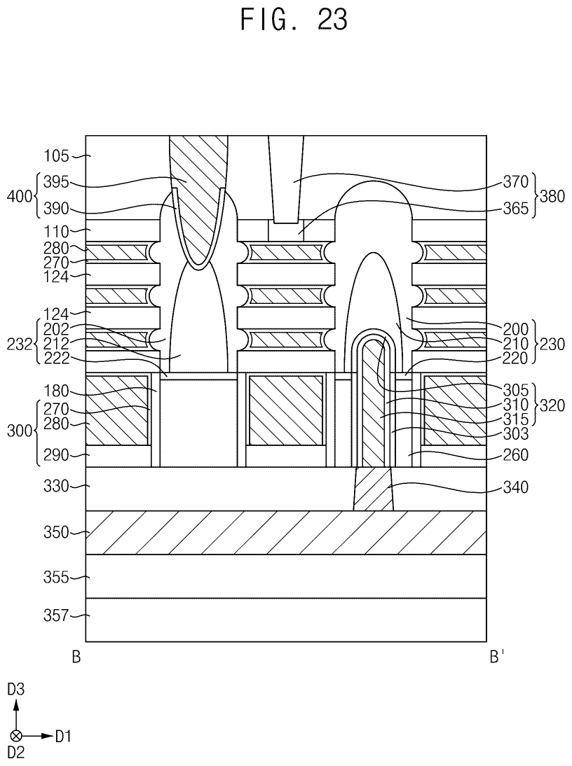

Referring to FIG. 23, a ninth opening may be formed by removing a portion of the active pattern 105 on the second source/drain layer 232 and a portion of the second source/drain layer 232 thereunder.

In example embodiments of the present inventive concept, the ninth opening may expose an inner sidewall of an upper portion of the fourth epitaxial pattern 202 and an upper surface of the third epitaxial pattern 212.

A second ohmic contact pattern 390 may be formed by performing, e.g., a selective deposition process on the exposed upper portion of the second source/drain layer 232. In example embodiments of the present inventive concept, the second ohmic contact pattern 390 may contact the fourth epitaxial pattern 202 and the third epitaxial pattern 212.

A second conductive layer may be formed on the active pattern 105, the division structure 380 and the second ohmic contact pattern 390, and a planarization process may be performed thereon to form a second conductive pattern 395 that fills a remaining portion of the ninth opening. The second ohmic contact pattern 390 and the second conductive pattern 395 may collectively form a second contact plug 400.

Referring back to FIGS. 1 to 3, a fifth insulating interlayer 410 may be formed on the active pattern 105, the isolation pattern 130 and the second contact plug 400, an etching process may be performed thereon to form a tenth opening exposing an upper surface of the second contact plug 400, and a second via 420 may be formed in the tenth opening.

A sixth insulating interlayer 430 may be formed on the fifth insulating interlayer 410 and the second via 420. An etching process may be performed thereon to form an eleventh opening exposing an upper surface of the second via 420, and a second wiring 440 may be formed to fill the eleventh opening.

In example embodiments of the present inventive concept, the second wiring 440 may extend in the first direction D1, and a plurality of second wirings 440 may be spaced apart from each other in the second direction D2. Each of the second wirings 440 may serve as a power rail.

The support substrate 357 may be flipped, and the support substrate 357 and the fourth insulating interlayer 355 may be removed to complete the manufacturing of the semiconductor device.

As described above, after flipping the substrate 100, an etching process may be performed on the upper portion of the active pattern 105 to form the seventh opening 360 that exposes the upper surface of the etch stop pattern 110, and the division structure 380 may be formed in the seventh opening 360.

If the etching stop pattern 110 is not formed, the seventh opening 360 may expose a portion of the gate structure 300, and thus the exposed portion of the gate structure 300 may be damaged in the etching process.

However, in example embodiments of the present inventive concept, the etch stop pattern 110 may be formed on the gate structure 300, so that the gate structure 300 might not be damaged in the etching process for forming the seventh opening 360, and thus, the semiconductor device may have improved electrical characteristics.

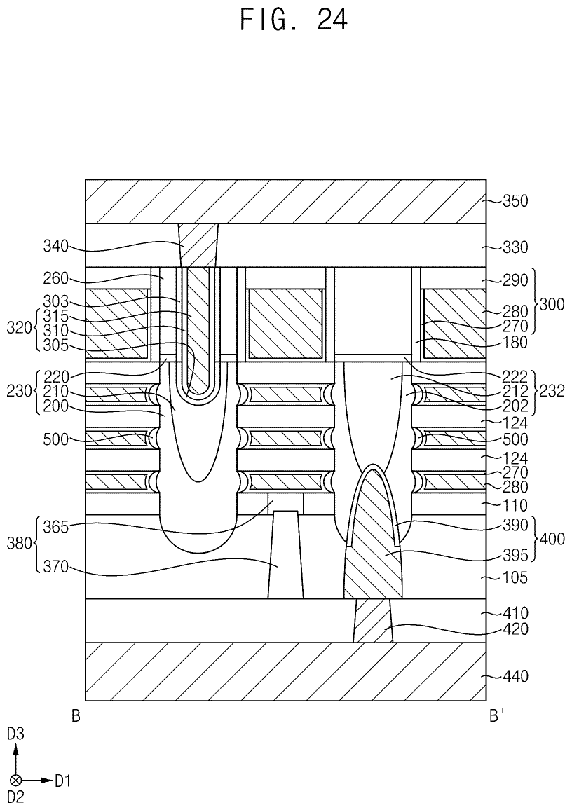

FIG. 24 is a cross-sectional view illustrating a semiconductor device in accordance with example embodiments of the present inventive concept, which corresponds to FIG. 3.

This semiconductor device may include elements substantially the same as or similar to those of the semiconductor device illustrated with reference to FIGS. 1 to 4 except for an inner spacer 500, and thus the same elements may be assigned the same reference numerals and repeated explanation thereof are omitted herein or briefly discussed.

Referring to FIG. 24, the inner spacer 500 may be disposed between the semiconductor patterns 124, and may cover each of opposite sidewalls in the first direction D1 of a portion of the gate structure 300 under the uppermost one of the semiconductor patterns 124. In an embodiment of the present inventive concept, the inner spacer 500 may have a cross-section taken along the second direction D2, which may have, e.g., a horseshoe shape or a semicircular shape with a recess on a sidewall thereof. The inner spacer 500 may include a nitride, e.g., silicon nitride.

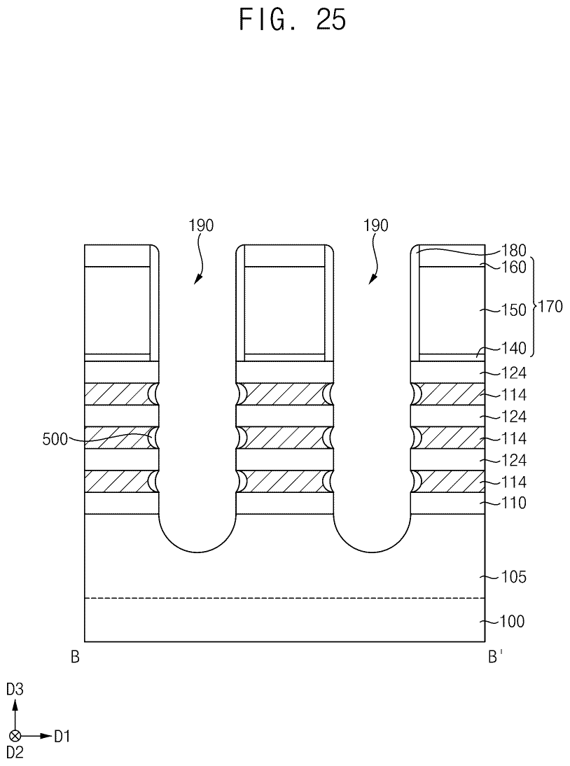

FIG. 25 is a cross-sectional view illustrating a method of manufacturing a semiconductor device in accordance with example embodiments of the present inventive concept.

This method may include processes substantially the same as or similar to those illustrated with reference to FIGS. 4 to 23 and FIGS. 1 to 3, and thus repeated explanations thereof are omitted herein.

Referring to FIG. 25, processes substantially the same as or similar to the processes illustrated with reference to FIGS. 5 to 11 may be performed, and an inner spacer 500 may be formed in the first recess 192.

In example embodiments of the present inventive concept, the inner spacer 500 may be formed by forming a spacer layer on inner walls of the first opening 190 and the first recess 192, and upper surfaces of the dummy gate structure 170 and the gate spacer 180, and anisotropically etching the spacer layer.

Thus, the inner spacer 500 may be formed to cover each of opposite sidewalls in the first direction D1 of each of the sacrificial patterns 114. In an embodiment of the present inventive concept, the inner spacer 500 may have a cross-section taken along the second direction D2, which may have a horseshoe shape or a semicircle shape with a recess in a sidewall.

Referring back to FIG. 24, processes that are substantially the same as or similar to the processes illustrated with reference to FIGS. 12 to 23 and 1 to 3 may be performed, and the semiconductor device may be manufactured.

While the present inventive concept has been described with reference to example embodiments thereof, it will be understood by those of ordinary skill in the art that various changes in form and details may be made thereto without departing from the spirit and scope of the present inventive concept.

What is claimed is:

1. A semiconductor device comprising:
an active pattern extending in a first direction and including a semiconductor material;
a gate structure disposed on the active pattern, and extending in a second direction crossing the first direction;
a plurality of channels spaced apart from each other in a third direction substantially perpendicular to the first and second directions, wherein each of the plurality of channels are disposed in the gate structure;
an etch stop pattern disposed on a lower surface of the gate structure;
first and second source/drain layers disposed at opposite sides, respectively, of the gate structure, wherein each of the first and second source/drain layers contact the plurality of channels;
a first contact plug disposed on an upper portion of the first source/drain layer; and
a division structure extending through the active pattern and the etch stop pattern, wherein the division pattern is disposed on a lower surface of the gate structure.

2. The semiconductor device according to claim 1, wherein the division structure includes:
a first division pattern having an upper surface contacting the lower surface of the gate structure; and
a second division pattern contacting a lower portion of the first division pattern, wherein the second division pattern has an upper surface narrower than a lower surface of the first division pattern.

3. The semiconductor device according to claim 2, wherein the first division pattern includes silicon oxide or silicon nitride, and
the second division pattern includes low-k material.

4. The semiconductor device according to claim 2, wherein a height of the upper surface of the first division pattern is substantially a same as a height of an upper surface of the etch stop pattern, and a height of a lowermost surface of the first division pattern is substantially the same as a height of a lower surface of the etch stop pattern.

5. The semiconductor device according to claim 2, wherein a width of the second division pattern increases from a top surface to a bottom surface thereof in the third direction.

6. The semiconductor device according to claim 1, wherein the etch stop pattern overlaps with the plurality of channels in the third direction.

7. The semiconductor device according to claim 1, wherein the etch stop pattern has a lower surface that is higher than a lowermost surface of the first source/drain layer.

8. The semiconductor device according to claim 1, further comprising a second contact plug contacting a lower portion of the second source/drain layer.

9. The semiconductor device according to claim 8, wherein:
the first contact plug includes:
a first conductive pattern;
a barrier pattern covering a sidewall and a lower surface of the first conductive pattern; and
a first ohmic contact pattern covering a lower surface of the barrier pattern, wherein the first ohmic contact pattern contacts the upper portion of the first source/drain layer, and the second contact plug includes:
a second conductive pattern; and
a second ohmic contact pattern covering an upper surface and a sidewall of an upper portion of the second conductive pattern, wherein the second ohmic contact pattern contacts the lower portion of the second source/drain layer.

10. The semiconductor device according to claim 1, wherein the etch stop pattern includes silicon or silicon germanium doped with one of oxygen, nitrogen and fluorine, or silicon-germanium doped with carbon.

11. The semiconductor device according to claim 1, wherein the gate structure includes a gate electrode and a gate insulation pattern covering at least a portion of a surface of the gate electrode, and
wherein the division structure contacts the gate insulation pattern.

12. A semiconductor device comprising:
a gate structure;
a plurality of channels extending in a first direction and disposed in the gate structure, wherein the plurality of channels are spaced apart from each other in a second direction that is substantially perpendicular to the first direction;
first and second source/drain layers disposed at opposite sides, respectively, of the gate structure, wherein each of the first and second source/drain layers contact the plurality of channels;
a division structure between the first and second source/drain layers, wherein the division structure includes:
a first division pattern having an upper surface contacting a lower surface of the gate structure; and
a second division pattern extending through and contacting a lower portion of the first division pattern, wherein the second division pattern has an upper surface that is narrower than a lower surface of the first division pattern.

13. The semiconductor device according to claim 12, further comprising an etch stop pattern covering each of opposite sidewalls in the first direction of the first division pattern.

14. The semiconductor device according to claim 13, wherein the etch stop pattern overlaps with the plurality of channels in the second direction.

15. The semiconductor device according to claim 13, wherein a height of an upper surface of the etch stop pattern is substantially a same as a height of an upper surface of the first division pattern, and a height of a lower surface of the etch stop pattern is substantially the same as a height of a lowermost surface of the first division pattern.

16. The semiconductor device according to claim 13, wherein a central portion of the gate structure contacts an upper surface of the first division pattern, and each of opposite side portions of the gate structure in the first direction contacts an upper surface of the etch stop pattern.

17. The semiconductor device according to claim 12, wherein a width of the second division pattern increases from a top surface to a bottom surface thereof in the second direction.

18. A semiconductor device comprising:
an active pattern extending in a first direction;
an isolation structure covering a sidewall of the active pattern in a second direction crossing the first direction;
a gate structure disposed on the active pattern, and extending in the second direction;
a plurality of channels spaced apart from each other in a third direction that is substantially perpendicular to the first and second directions, wherein each of the plurality of channels are covered by the gate structure;
an etch stop pattern contacting a lower surface of the gate structure;
first and second source/drain layers disposed at each of opposite sides, respectively, of the gate structure, wherein each of the first and second source/drain layers contact the plurality of channels;
a first contact plug disposed on and contacting an upper portion of the first source/drain layer;
a second contact plug disposed on and contacting a lower portion of the second source/drain layer;
a division structure disposed between the first source/drain layer and the second source/drain layer, wherein the division structure includes:
a first division pattern having an upper surface contacting the lower surface of the gate structure; and
a second division pattern extending through the active pattern and a lower portion of the first division pattern and contacting the first division pattern, wherein the second division pattern has an upper surface that is narrower than a lower surface of the first division pattern; and
first and second wirings electrically connected to the first and second contact plugs, respectively.

19. The semiconductor device according to claim 18, wherein a height of an upper surface of the etch stop pattern is substantially a same as a height of an upper surface of the first division pattern, and a height of a lower surface of the etch stop pattern is substantially the same as a height of a lowermost surface of the first division pattern.

20. The semiconductor device according to claim 18, wherein a lower surface of a central portion of the gate structure contacts an upper surface of the first division pattern, and each of opposite side portions of the gate structure in the first direction contacts an upper surface of the etch stop pattern.
